(19) United States
(12) Patent Application Publication
(10) Pub. No.: US 2005/0104227 A1
(43) Pub. Date: May 19, 2005

(54) Substrate-based package for integrated circuits

(76) Inventors: Stephan Blaszczak, Freyburg (DE); Martin Reiss, Medingen (DE); Bernd Scheibe, Dresden (DE)

Correspondence Address: SLATER & MATSIL, L.L.P., 17950 PRESTON RD, SUITE 1000, DALLAS, TX, 75252-5793, US

(21) Appl. No.: 10/961,473

(22) Filed: Oct. 8, 2004

(30) Foreign Application Priority Data
Oct. 9, 2003 (DE) 103 47 621.0

(51) Int. Cl. H01L 21/44; H01L 23/48

(52) U.S. Cl. 257/782; 257/783; 438/118; 257/737

(57) ABSTRACT

A substrate-based package for integrated circuits includes a substrate on which at least one chip is attached by a die-attach material. The substrate has, on the side that is opposite from the chip, conductor tracks that are provided with solder balls and are connected to the chip by means of wire bridges that extend through a bonding channel, which is sealed by an encapsulating compound. The chip and parts of the substrate on the chip side are covered by a mold cap. The backside of the chip is provided at least partially with regions with a distinctly enlarged surface as a result of greater roughness by etching or mechanical working. The regions of greater roughness have a predetermined depth on the backside of the chip and also are able to be configured as crossing tracks.

This application claims priority to German Patent Application 103 47 621.0, which was filed Oct. 9, 2003, and is incorporated herein by reference.

### TECHNICAL FIELD

The invention relates to a substrate-based package for integrated circuits.

### BACKGROUND

Such substrate-based IC packages are also referred to as BGA packages, BGA standing for Ball Grid Array. U.S. Pat. No. 6,048,755 A discloses such a BGA package. It goes without saying that a number of packages may also be arranged on a common substrate strip (matrix strip). The substrate on which the chips are arranged comprises a customary PCB (Printed Circuit Board), generally of a glassfibre laminate.

In the case of such substrate-based packages, the mold cap (covering material or molding compound), which consists of a plastics material, serves for protection of the chip and in particular protection of the chip edges, since cracks or other mechanical damage which may be caused by the handling during the back-end process, or else with the customer, can also have an effect on the active chip side. The mold cap in this case encloses the backside of the chip and also the edges of the chip and adjacent regions of the substrate, whereby the warping characteristics (bending characteristics) of the package are decisively influenced.

In the case of such a package, the chip can be fixed on the substrate in various ways. For example, the chips are attached by means of a tape or a printed or dispensed adhesive. It is particularly effective to print the adhesive onto the substrate with a printing template interposed and subsequently to adhesively attach a number of chips to the substrate. The matrix strips already mentioned are understood as meaning substrates which are intended for receiving a plurality of chips next to one another.

In the case of these substrate-based packages for integrated circuits, in particular in the case of Ball Grid Arrays with backside protection, there continue as before to be difficulties with respect to their reliability. This relates in particular to the thermal cycles at module level. The failures caused as a result are attributable in particular to detachment of the solder balls during thermal cycling, that is when testing the packages by subjecting them to the entire range of operating temperatures.

The detachments of the solder balls are essentially a result of the different coefficients of expansion (warping characteristics) of the individual components of the package (chip, substrate, PCB and the board on which the package is mounted). This problem has an effect in particular in the case of very large chips, since here the forces on the solder balls in critical positions are particularly great.

To reduce these problems, it has been attempted, by design changes in the ballout of the package, to use special solder stop masks, or a special form of the solder pads, and alternatively or additionally to use optimized mounting materials. However, for time reasons alone, it is not possible to be constantly adapting the mounting materials to the chip size, since the adaptation of materials always requires a very long lead time.

### SUMMARY OF THE INVENTION

In one aspect, the invention provides a substrate-based package for integrated circuits in which the warping characteristics are improved and which is suitable in particular for very large chips. The preferred embodiment provides a substrate-based package for integrated circuits, which is in electrical contact with the molding compound, and is provided at least partially with regions with a distinctly enlarged surface.

The partly enlarged surface of the backside of the chip allows the warping characteristics of the module (i.e., the bowing of the package) to be influenced quite decisively, in that regions of lower adhesion of the molding compound alternate with regions of higher adhesion. In particular, the warping characteristics of large chips can be influenced in this way, with the result that adaptation of the chip size to the package is possible.

In continuation of the invention, the regions of an enlarged surface of the backside of the chip have greater roughness.

A further continuation of the invention provides forming the regions of greater roughness of the surface as an etched area. Such regions of greater roughness can be realized very easily by means of known etching processes.

The regions of greater roughness of the surface may also be configured as mechanically patterned areas, which is possible for example by wet grinding.

One particular refinement of the invention provides that the regions of greater roughness have a predetermined depth on the backside of the chip. This allows the warping characteristics to be additionally influenced.

For instance, the regions with a partially enlarged surface on the backside of the chip may be configured as crossing tracks, for example tracks crossing at right angles.

One specific refinement of the invention provides that the regions of a partially enlarged surface on the backside of the chip are configured as tracks running parallel to one another.

A further refinement of the invention is characterized in that the regions of a partially enlarged surface on the backside of the chip are configured as tracks arranged in a checkerboard manner.

Finally, it is provided that the solder balls on the substrate side are arranged underneath the non-patterned regions of the backside of the chip.

### BRIEF DESCRIPTION OF THE DRAWINGS

The invention is to be explained in more detail below on the basis of an exemplary embodiment. In the associated drawings:

FIG. 1 shows a schematic sectional representation of a package according to the invention;

FIG. 2 shows a plan view of a chip with a modified backside; and

FIG. 3 shows a plan view of a further variant of a chip with a modified backside.

The following list of reference symbols can be used in conjunction with the figures:
1 substrate
2 solder stop lacquer
3 chip
4 die-attach material
5 solder ball
6 wire bridge
7 bonding channel
8 glob top
9 mold cap
10 edge
11 region
12 track

### DETAILED DESCRIPTION OF ILLUSTRATIVE EMBODIMENTS

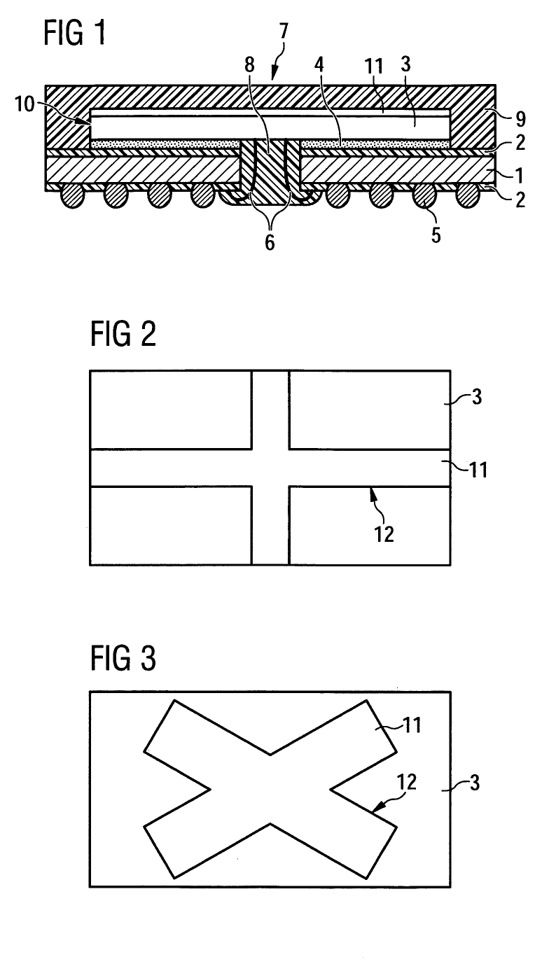

Referring first to FIG. 1, the substrate-based package according to the preferred embodiment of the invention for integrated circuits includes a substrate 1, which is coated on both sides with a solder stop lacquer 2 and on which a chip 3 is attached by a die-attach material 4 (e.g., tape). Furthermore, the substrate 1 has, on the side that is opposite from the chip 3, conductor tracks (not shown) provided with solder balls 5. These conductor tracks are connected to the chip 3 by way of wire bridges 6, which extend through a bonding channel 7. For protection of the wire bridges 6, the bonding channel 7 is sealed by a glob top 8 (e.g., non-conducting plastic with low coefficient of thermal expansion). Furthermore, the chip 3 and parts of the substrate 1 on the chip side are covered by a mold cap 9, which serves for protection of the backside of the chip 3 and in particular protection of the very sensitive edges 10 of the chip 3.

In order to influence the warping characteristics of the package, the backside of the chip 3 is provided at least partially with regions 11 with a distinctly enlarged surface, which is achieved by the regions 11 having greater roughness in comparison with the remaining backside of the chip 3.

This can be achieved by the regions 11 of greater roughness of the surface being created by customary etching processes or else by purely mechanical working.

The greater roughness of the regions 11 achieves the effect of much greater adhesive strength between the backside of the chip 3 and the mold cap 9, with the result that the warping characteristics can be influenced well, in that thermally induced forces are mainly transferred partially to the mold cap 9.

However, the warping characteristics of the chip 3 are also influenced directly, since the regions of greater roughness have at the same time a smaller thickness of the chip 3.

The regions 11 of a partially enlarged surface on the backside of the chip 3 may be configured as tracks 12 crossing in a wide range of angles, as shown in FIG. 2.

For example, the regions 11 with a partially enlarged surface on the backside of the chip 3 may be configured as tracks 12 crossing at right angles.

It is also possible to configure the regions 11 with a partially enlarged surface on the backside of the chip 3 as tracks 12 running parallel to one another or tracks 12 running in a checkerboard manner, the solder balls 5 on the substrate side being arranged under the non-patterned regions 11 of the backside of the chip 3. FIG. 3 shows one such alternate arrangement of regions 1.

1. A substrate-based package for integrated circuits, the substrate-based package comprising:
a substrate;
at least one chip attached to the substrate by a die-attach material;
a mold cap that covers the chip and the substrate on the chip side; and
adhesive regions disposed on a backside of the chip between the chip and the mold cap, the adhesive regions having a distinctly enlarged surface so that warping characteristics of the substrate-based package are affected by the adhesive regions.

2. The substrate-based package according to claim 1, wherein the adhesive regions have greater roughness than the backside of the chip.

3. The substrate-based package according to claim 2, wherein the adhesive regions of greater roughness comprise etched areas.

4. The substrate-based package according to claim 2, wherein the adhesive regions of greater roughness comprise mechanically patterned areas.

5. The substrate-based package according to claim 2, wherein the adhesive regions have a predetermined depth on the backside of the chip.

6. The substrate-based package according to claim 1, wherein the adhesive regions are configured as crossing tracks.

7. The substrate-based package according to claim 6, wherein the adhesive regions are configured as tracks crossing at right angles.

8. The substrate-based package according to claim 1, wherein the adhesive regions are configured as tracks running parallel to one another.

9. The substrate-based package according to claim 1, wherein the adhesive regions are configured as tracks arranged in a checkerboard manner.

10. The substrate-based package according to claim 1, further comprising solder balls electrically coupled to the conductor tracks.

11. The substrate-based package according to claim 10, wherein the solder balls are arranged beneath non-patterned regions of the backside of the chip.

12. A substrate-based package for integrated circuits, the substrate-based package comprising:
a substrate;
at least one chip attached to the substrate by a die-attach material;
conductor tracks disposed on the substrate on a side that is opposite from the chip;
wire bridges that electrically couple the solder balls to the chip, the wire bridges extending through a bonding channel that extends through the substrate;
solder balls electrically coupled to the conductor tracks;
a glob top that seals the bonding channel;
a mold cap that covers the chip and the substrate on the chip side; and
adhesive regions disposed on a backside of the chip, the adhesive regions having a distinctly enlarged surface so that warping characteristics of the substrate-based package are affected by the adhesive regions.

13. The substrate-based package according to claim 1, wherein the adhesive regions have greater roughness than the backside of the chip.

14. A method of making a packaged integrated circuit, the method comprising:
providing a semiconductor chip;
forming regions of material over a backside of the semiconductor chip, the regions of material formed in a pattern that covers portions of the backside of the semiconductor chip;
roughening the regions of material;
adhering a frontside of the semiconductor chip to a substrate;
electrically connecting the frontside of the semiconductor chip to the substrate; and
forming a mold cap over the backside of the semiconductor chip.

15. The method according to claim 14, wherein roughening the regions of material comprises mechanically patterning the regions of material.

16. The method according to claim 14, wherein roughening the regions of material comprises etching the regions of material.

17. The method according to claim 14, wherein forming regions of material comprises forming regions of material that are configured as crossing tracks.

18. The method according to claim 15, wherein forming regions of material comprises forming regions of material that are configured as tracks crossing at right angles.

19. The method according to claim 12, wherein forming regions of material comprises forming regions of material that are configured as tracks running parallel to one another.

20. The method according to claim 12, wherein forming regions of material comprises forming regions of material that are configured as tracks arranged in a checkerboard manner.
